(19) United States
(12) Patent Application Publication
(10) Pub. No.: US 2005/0013450 A1
(43) Pub. Date: Jan. 20, 2005

(54) Waveform equalizer

(75) Inventor: Machiya Kumazawa, Osaka (JP)

Correspondence Address: Jack Q. Lever, Jr.;McDERMOTT, WILL & EMERY, 600 Thirteenth Street, N.W., Washington, DC, 20005-3096, US

(73) Assignee: MATSUSHITA ELECTRIC INDUSTRIAL CO., LTD.

(21) Appl. No.: 10/891,102

(22) Filed: Jul. 15, 2004

(30) Foreign Application Priority Data
Jul. 18, 2003 (JP) 2003-276503

(51) Int. Cl. H03G 5/00

(52) U.S. Cl. 381/103; 333/28 R

(57) ABSTRACT

A waveform equalizer includes: a digital filter for performing convolution operation for a plurality of tap values each of which is obtained by delaying an input signal for a given amount of time and a plurality of tap coefficients corresponding to those tap values, thereby generating an output signal; an error detector for detecting an error in the output signal from the digital filter; a tap-coefficient update unit for updating the tap coefficients based on the error detected by the error detector; and an operation accuracy control unit for calculating operation accuracy control values that correspond to respective taps in the digital filter. The digital filter changes accuracy with which the convolution operation is performed, in accordance with the operation accuracy control values calculated by the operation accuracy control unit.

### BACKGROUND OF THE INVENTION

The present invention relates to waveform equalizers which adaptively equalize digital modulating signals.

Along with the recent advancement of digital communication technology and semiconductor technology, digitalization of television broadcasting has been promoted. Under these circumstances, various kinds of transmission channels are used in digital broadcasting, such that they are not uniformly of high quality. To minimize transmission deterioration in transmission channels, adaptively controlled waveform equalizers are used to compensate for characteristics of the transmission channels.

A waveform equalizer typically includes a number of multipliers which perform relatively highly accurate multiplications, which causes a problem in that circuit size and power consumption are increased. The conventional solution to this problem is to decrease the bit length of a prediction error in a signal outputted from the waveform equalizer and give the prediction error with the reduced bit length to the multipliers that calculate tap coefficients. In this manner, the circuit size and power consumption are reduced (see Japanese Laid-Open Publication No. 9-97477 (page 4, FIG. 1), for example.)

In the conventional waveform equalizer, however, all of the multipliers that calculate the tap coefficients are always under operating conditions, so that power consumption is still large. In addition, since operation accuracy is fixed, the waveform equalizer needs to have an operational unit, which is commensurate with the fixed operation accuracy, that is, which is of relatively large size. Consequently, the circuit size of the entire waveform equalizer is still large.

### SUMMARY OF THE INVENTION

In view of the above problem, an object of the present invention is to reduce power consumption and circuit area of a waveform equalizer.

In order to solve the above problem, an inventive waveform equalizer includes: a digital filter for performing convolution operation for a plurality of tap values each of which is obtained by delaying an input signal for a given amount of time and a plurality of tap coefficients corresponding to those tap values, thereby generating an output signal; an error detector for detecting an error in the output signal from the digital filter; a tap-coefficient update unit for updating the tap coefficients based on the error detected by the error detector; and an operation accuracy control unit for calculating operation accuracy control values that correspond to respective taps in the digital filter. The digital filter changes accuracy with which the convolution operation is performed, in accordance with the operation accuracy control values calculated by the operation accuracy control unit.

According to the present invention, when the digital filter adaptively equalizes the waveform of the input signal, the accuracy of the convolution operation is changed in accordance with the operation accuracy control values calculated by the operation accuracy control unit. Thus, when the output signal has substantially converged to a desired signal, for example, the accuracy of the convolution operation in the digital filter is reduced to achieve a decrease in power consumption.

Specifically, the operation accuracy control unit has size-comparing units each of which compares in terms of size one of the tap coefficients with a predetermined threshold value corresponding to the tap coefficient, and then outputs comparison result as the operation accuracy control value corresponding to the tap coefficient.

Also, specifically, the digital filter includes multiplier units each of which performs a multiplication for one of the tap values and the tap coefficient corresponding to the tap value and changes effective bit length in accordance with the operation accuracy control value corresponding to the tap value.

More specifically, each of the multiplier units has an information acquiring unit for acquiring at least either one or more higher-order bits or one or more lower-order bits of an associated one of the tap coefficients, and if the operation accuracy control value instructs to lower the accuracy of the convolution operation in the digital filter, the multiplier unit masks either the higher-order or lower-order bits of the tap coefficient acquired by the information acquiring unit.

Preferably, the inventive waveform equalizer further includes a signal quality evaluation unit for evaluating quality of the output signal from the digital filter. And the operation accuracy control unit calculates the operation accuracy control values from a quality evaluation value generated by the signal quality evaluation unit, and if the quality evaluation value indicates that the quality of the output signal is relatively low, the operation accuracy control unit calculates the operation accuracy control values so that the accuracy of the convolution operation in the digital filter is raised, while if the quality evaluation value indicates that the quality of the output signal is relatively high, the operation accuracy control unit calculates the operation accuracy control values so that the accuracy is lowered.

Then, the waveform equalization procedure is carried out, with the quality of the output signal being fed back. This minimizes deterioration in characteristic, while allowing a reduction in power consumption.

Specifically, the operation accuracy control unit includes: an evaluation-value storing unit for storing a past quality evaluation value of the output signal; a comparison unit for comparing a new quality evaluation value of the output signal with the quality evaluation value stored in the evaluation-value storing unit; a plurality of operation accuracy control sub-units which are provided corresponding to the respective taps in the digital filter, and each of which calculates a corresponding one of the operation accuracy control values; and a control unit for controlling the operation accuracy control sub-units in a time-sharing manner. And if a comparison result from the comparison unit indicates that the new quality of the output signal is higher than the past quality of the output signal, each of the operation accuracy control sub-units calculates the operation accuracy control value so that the accuracy of the convolution operation in the digital filter is lowered, while if the comparison result indicates that the new quality of the output signal is lower than the past quality, each of the operation accuracy control sub-units calculates the operation accuracy control value so that the accuracy is raised.

In the inventive waveform equalizer, the digital filter preferably allocates operation resources that the waveform equalizer has, among the respective taps in accordance with the operation accuracy control values.

Then, a relatively small amount of operation resources is allocated to the taps that no longer require highly accurate operations, while a relatively large amount of operation resources is allocated to the taps that require highly accurate operations. In other words, the limited operation resources are allocated optimally, which allows a reduction in the amount of operation resources that the waveform equalizer should have. As a result, the circuit size of the waveform equalizer is decreased.

According to the present invention, high operation accuracy is allocated to tap-coefficient operations for taps that greatly contribute to digital-filtered results, while low operation accuracy is allocated to tap-coefficient operations for taps whose contribution is small, thereby achieving a reduction in power consumption by the waveform equalizer. In addition, even if the number of operational units provided is reduced for a reduction in circuit area, adaptive control is performed to minimize deterioration in characteristic.

### BRIEF DESCRIPTION OF THE DRAWINGS

FIG. 1 illustrates the configuration of a waveform equalizer in accordance with a first embodiment of the present invention.

FIG. 2 illustrates the internal configuration of an operation accuracy control unit in the waveform equalizer of FIG. 1.

FIG. 3 illustrates the internal configuration of a digital filter in the waveform equalizer of FIG. 1.

FIG. 4 illustrates the internal configuration of a multiplier unit in the digital filter of FIG. 3.

FIG. 5 illustrates the configuration of a waveform equalizer in accordance with a second embodiment of the present invention.

FIG. 6 illustrates the internal configuration of an operation accuracy control unit in the waveform equalizer of FIG. 5.

FIG. 7 illustrates the configuration of a digital filter in accordance with a third embodiment of the present invention.

### DESCRIPTION OF THE PREFERRED EMBODIMENTS

Hereinafter, embodiments of the present invention will be described with reference to the accompanying drawings.

(First Embodiment)

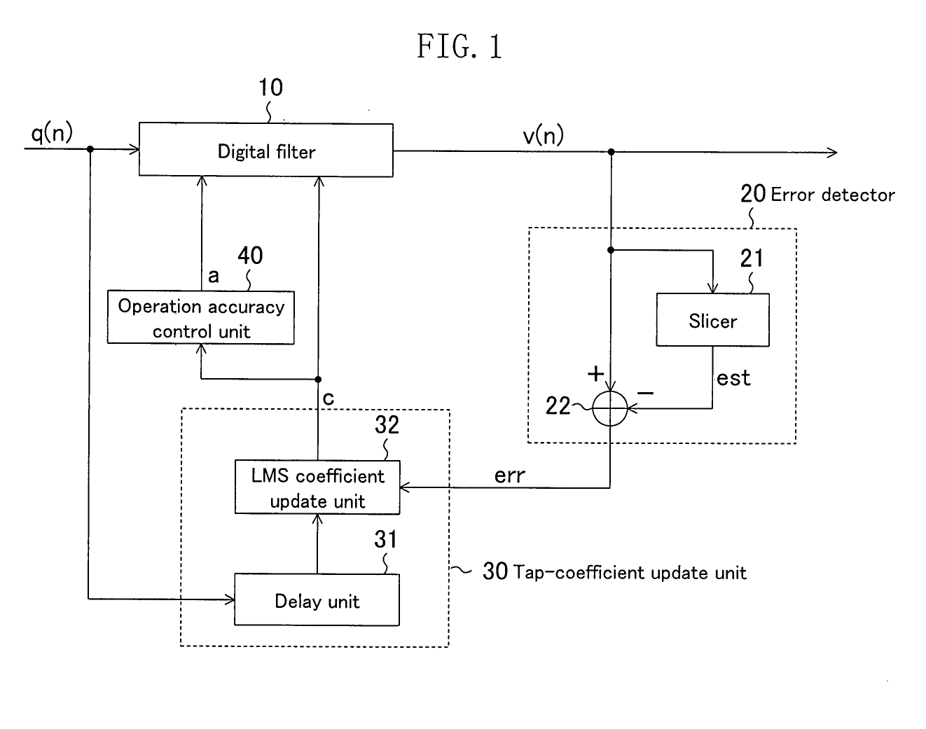

FIG. 1 illustrates the configuration of a waveform equalizer in accordance with a first embodiment of the present invention. The waveform equalizer of this embodiment is furnished with a digital filter 10, an error detector 20, a tap-coefficient update unit 30, and an operation accuracy control unit 40.

The digital filter 10 uses a plurality of tap coefficients c outputted from the tap-coefficient update unit 30 and a plurality of operation accuracy control values a outputted from the operation accuracy control unit 40, to subject an input signal q(n) to a digital filtering process, thereby generating an output signal v(n). The digital filter 10 will be explained in detail later.

When the output signal v(n) is inputted to the error detector 20, the error detector 20 outputs an error signal err. More specifically, a slicer 21 calculates an estimated value of a desired signal existing in the output signal v(n) by hard decision and generates an estimated signal est. Then, a subtractor 22 subtracts the estimated signal est from the output signal v(n), whereby an error component is calculated and outputted as the error signal err.

The tap-coefficient update unit 30 updates the tap coefficients c based on the input signal q(n) and the error signal err. More specifically, in a delay unit 31, the input signal q(n) is compensated for a signal delay in the digital filter 10. Then, in an LMS coefficient update unit 32, the tap coefficients c are adaptively calculated from the output from the delay unit 31 and the error signal err by using a typical LMS coefficient update algorithm.

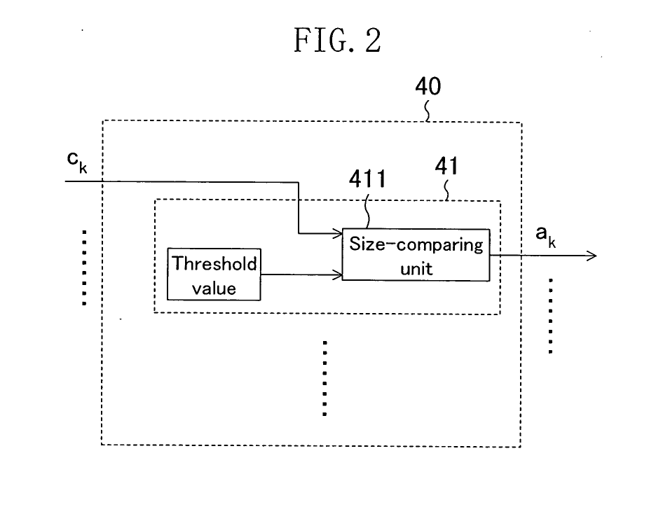

The operation accuracy control unit 40 receives the tap coefficients c and outputs the operation accuracy control values a. FIG. 2 illustrates the internal configuration of the operation accuracy control unit 40. The operation accuracy control unit 40 includes a plurality of operation accuracy determination units 41, each of which generates an operation accuracy control value aₖ in accordance with a respective tap coefficient cₖ. Each operation accuracy determination unit 41 compares in a size comparing unit 411 the size of a supplied tap coefficient cₖ with the size of a corresponding given threshold value. If the tap coefficient cₖ is greater than the threshold value, “1” is outputted as the operation accuracy control value aₖ. In the other cases, “0” is outputted.

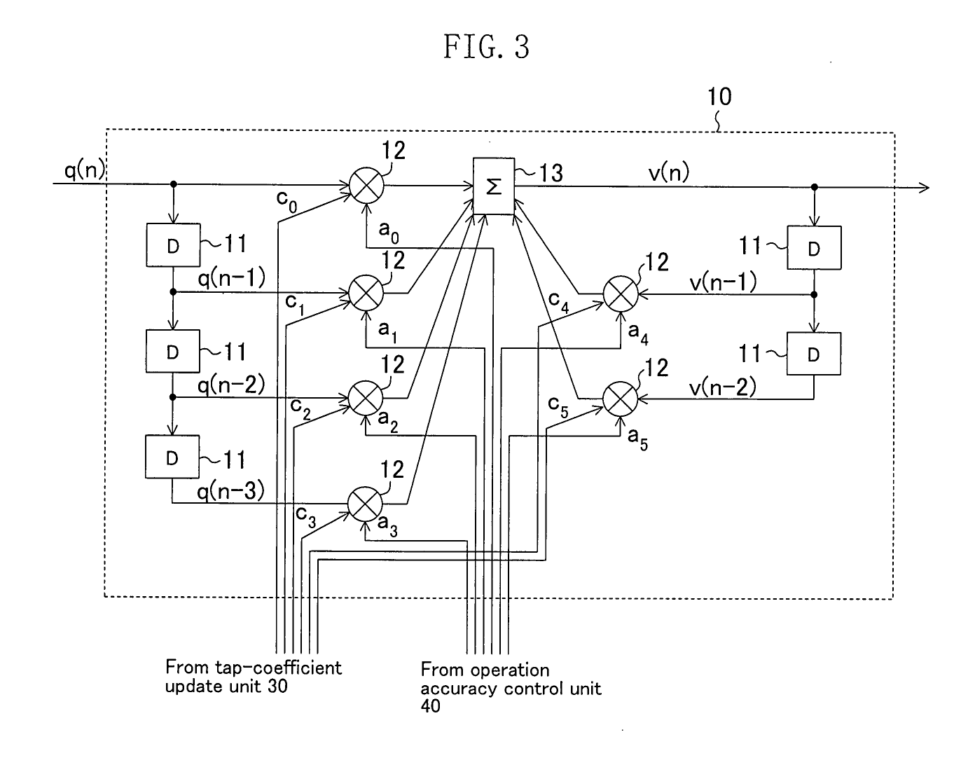

Next, the digital filter 10 will be explained in detail. FIG. 3 illustrates the internal configuration of the digital filter 10. In the digital filter 10, a FIR digital filter and an IIR digital filter are cascade-connected to each other. The FIR digital filter is composed of three delay units 11 for delaying the input signal q(n) for a given amount of time to generate tap values q(n−1), q(n−2), and q(n−3), respectively; four multiplier units 12 for multiplying the tap values q(n) through q(n−3) by their respective corresponding tap coefficients co through C₃; and an adder 13 for adding the outputs from the multiplier units 12 together. The IIR digital filter is composed of the adder 13; two delay units 11 for delaying the output signal v(n) for a given amount of time to generate tap values v(n−1) and v(n−2), respectively; and two multiplier units 12 for multiplying the tap values v(n−1) and v(n−2) by their respective corresponding tap coefficients C₄ and c₅. The digital filter 10 performs a convolution operation on each tap value and its corresponding tap coefficient to generate the output signal v(n). The configuration of the digital filter 10 is merely as an example provided for the sake of description, and any numbers of delay units 11 and multiplier units 12 may be provided.

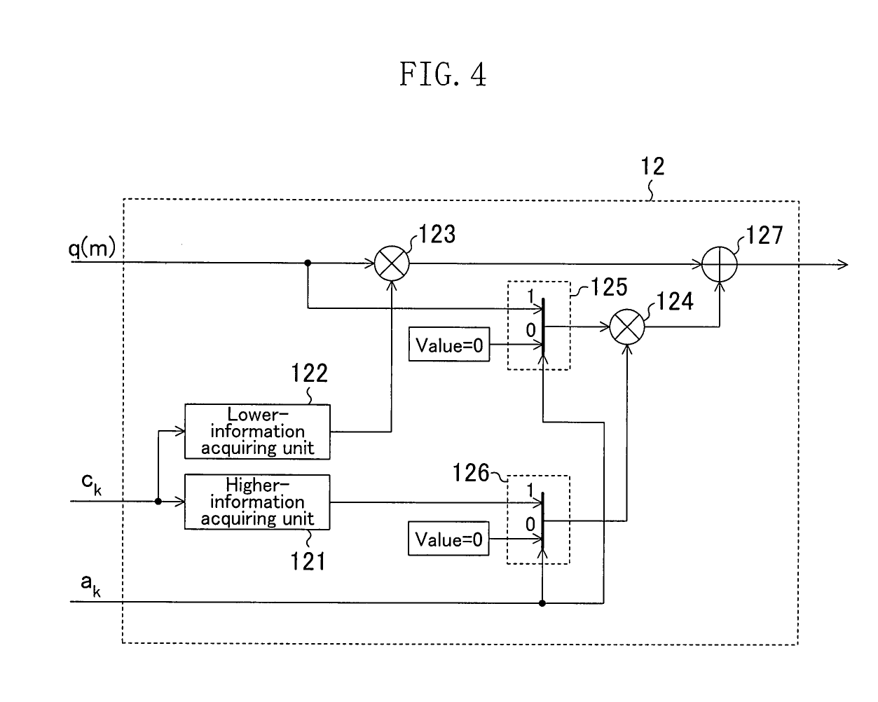

Each multiplier unit 12 can change effective bit length in accordance with the operation accuracy control value aₖ. FIG. 4 illustrates the internal configuration of the multiplier unit 12. A higher-information acquiring unit 121 acquires higher-order bit(s) of the tap coefficient cₖ. A lower-information acquiring unit 122 acquires lower-order bit(s) of the tap coefficient cₖ. The lower-order bit(s) of the tap coefficient cₖ is multiplied by a tap value q(m) by a multiplier 123.

On the other hand, whether or not the higher-order bit(s) of the tap coefficient cₖ is multiplied by the tap value q(m) by a multiplier 124 is determined in accordance with the operation accuracy control value aₖ. More specifically, if the operation accuracy control value aₖ is “1”, the tap value q(m) is selected by a signal selection unit 125, and the higher-order bit(s) of the tap coefficient cₖ is selected by a signal selection unit 126, whereby the tap value q(m) is multiplied by the higher-order bit(s) of the tap coefficient cₖ by the multiplier 124. On the other hand, if the operation accuracy control value aₖ is “0”, “0” is selected in the signal selection units 125 and 126. The multiplier 124 thus does not perform any multiplication with respect to the higher-order bit(s) of the tap coefficient cₖ. An adder 127 adds together the respective multiplication results obtained by the multipliers 123 and 124, thereby generating an output which is produced from the multiplier unit 12.

When the operation accuracy control value aₖ is “1”, the multiplier unit 12 performs the operation with the highest accuracy, that is, with accuracy equal to that of a multiplier provided in a conventional waveform equalizer. When the operation accuracy control value aₖ is “0”, on the other hand, the multiplier 124, which is a part of the multiplier unit 12, stops operating, because the tap value q(m) and the higher-order bit(s) of the tap coefficient cₖ are masked by the signal selection units 125 and 126, respectively. As a result, the multiplier unit 12 performs the operation with lower accuracy than the multiplier in the conventional waveform equalizer.

When the output signal v(n) from the digital filter 10 has substantially converged to a desired signal, the digital filter 10 no longer needs to perform the waveform equalization procedure with high accuracy, and even if the accuracy is lowered, no deterioration will be caused in the quality of the output signal. By decreasing the accuracy, that is, by halting part of the operation of the multiplier unit 12, power consumption is reduced.

As described above, in this embodiment, part of the operation of the operational units is halted when tap-coefficient operations that do not require operation accuracy are performed. This allows a reduction in electric power consumed by the waveform equalizer, which is composed of the many operational units and thus likely to consume much power.

In the multiplier units 12, although the higher-order bit(s) of the tap coefficient cₖ is masked to decrease operation accuracy, the lower-order bit(s) thereof may be masked instead.

In addition, although the operation accuracy is changed in two levels in the multiplier units 12, it may be changed in three or more levels. Even in that case, effects similar to those described above are achieved.

Furthermore, the multiplier units 12 may be designed so as to output “0” as multiplication result when the supplied tap coefficient cₖ is equal to or lower than a given threshold value.

Moreover, the error detector 20 may be designed so as to calculate an error component when a signal outputted from an error correction unit, which is provided in a stage after the waveform equalizer, is inputted to the error detector 20.

Also, the operation accuracy control unit 40 may be designed so as to halt or restart operation in accordance with a signal from an external device.

Furthermore, in this embodiment, although the convolution operation accuracy in the digital filter 10 is changed by adaptively controlling the operation accuracy of the multiplier units 12, the present invention is not limited to this. It is possible to change the convolution operation accuracy in the digital filter 10 by adaptively controlling the accuracy of the tap values and/or of the adder 13.

(Second Embodiment)

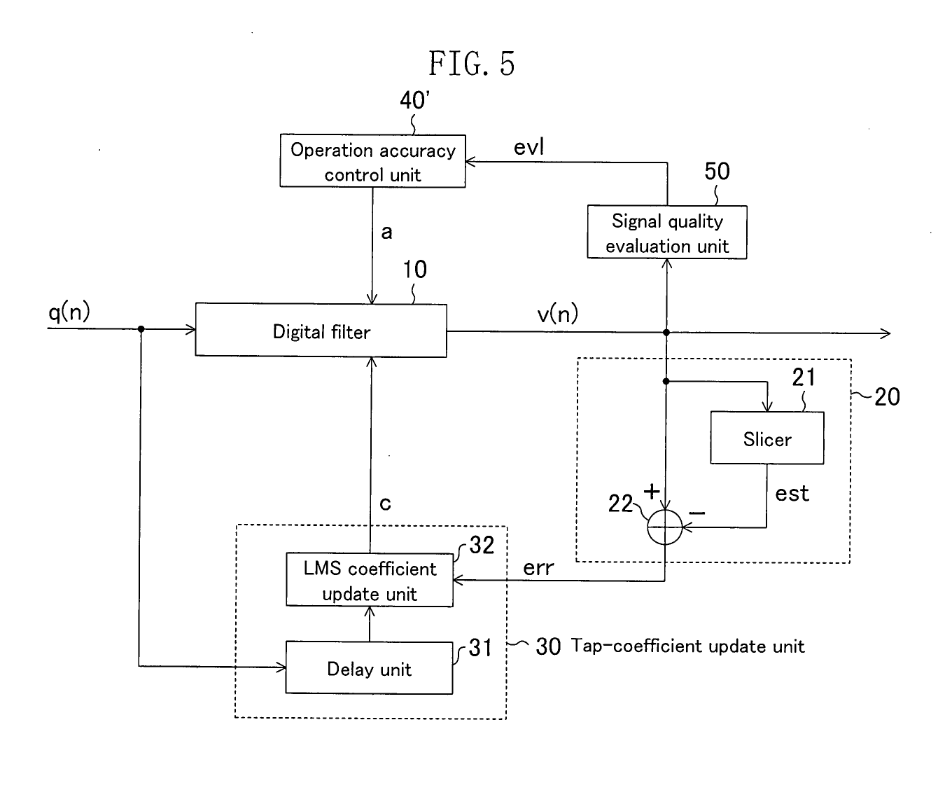

FIG. 5 illustrates the configuration of a waveform equalizer in accordance with a second embodiment of the present invention. The waveform equalizer of this embodiment includes an operation accuracy control unit 40′, which differs from that of the waveform equalizer of the first embodiment, and a signal quality evaluation unit 50. The other components of the waveform equalizer of this embodiment are the same as those of the first embodiment, and the description thereof will be thus omitted herein.

The signal quality evaluation unit 50 evaluates the quality of an output signal v(n) from a digital filter 10 and outputs a quality evaluation value evl. More specifically, the signal quality evaluation unit 50 outputs as the quality evaluation value evl one of a phase error, an amplitude error, a C/N value, a demodulator output bit error rate, a Viterbi decoder output bit error rate, and a Reed-Solomon decoder output packet error rate, or a weighted sum of two or more of these values.

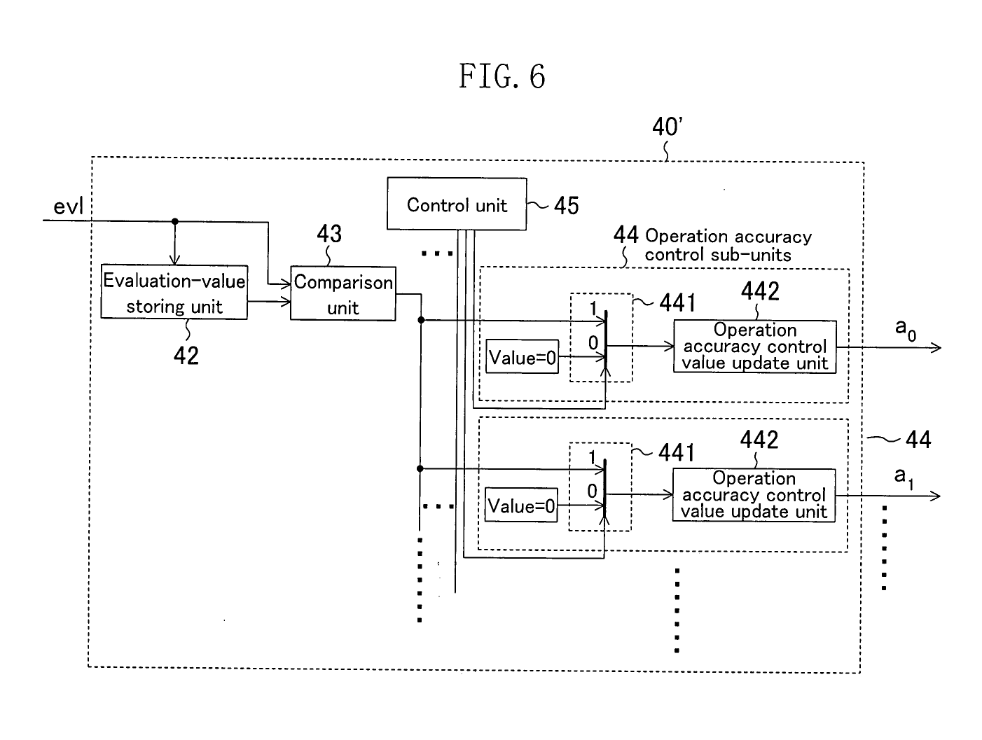

The operation accuracy control unit 40′ generates operation accuracy control values a based on the quality evaluation value evi from the signal quality evaluation unit 50. FIG. 6 illustrates the internal configuration of the operation accuracy control unit 40′. The operation accuracy control unit 40′ includes an evaluation-value storing unit 42 for storing a past quality evaluation value; a comparison unit 43 for comparing a newly supplied quality evaluation value with the past quality evaluation value stored in the evaluation-value storing unit 42; a plurality of operation accuracy control sub-units 44 each of which calculates a respective operation accuracy control value aₖ; and a control unit 45 for performing time sharing control of the operation accuracy control sub-units 44.

When a new quality evaluation value evl is supplied to the operation accuracy control unit 40′, the comparison unit 43 makes a comparison between the past quality evaluation value and the new quality evaluation value. The evaluation-value storing unit 42 newly stores the new quality evaluation value evl as a past quality evaluation value, or may retain an average value of the past quality evaluation values. As a result of the comparison by the comparison unit 43, when it is determined that the new quality evaluation value evl has remained the same as the present state or become better, the operation accuracy control sub-units 44 are instructed to lower operation accuracy. On the other hand, when the quality evaluation value is determined to have deteriorated, an instruction to raise the operation accuracy is given.

The operation accuracy control sub-units 44 are controlled in a time-sharing manner by the control unit 45. When a signal received from the control unit 45 is “0”, a signal selection unit 441 in the operation accuracy control sub-units 44 selects a fixed value “0”. At this time, an operation accuracy control value update unit 422 in the operation accuracy control sub-units 44 does not update the operation accuracy control value aₖ. On the other hand, when the signal received from the control unit 45 is “1”, the signal selection unit 441 selects an output from the comparison unit 43. This makes the operation accuracy control value update unit 422 update the operation accuracy control value aₖ and store a new operation accuracy control value aₖ. The time sharing control of the operation accuracy control sub-units 44 may be performed in such a manner that any one of the operation accuracy control sub-units 44 operates, or that two or more of the operation accuracy control sub-units 44 operate at the same time.

Since the operation accuracy control sub-units 44 are controlled in the time-sharing manner, all of the operation accuracy control sub-units 44 do not operate at the same time, thereby reducing power consumption. In addition, it is sufficient that only one comparison unit 43 be provided, which permits the circuit size of the waveform equalizer to be decreased.

As described above, in this embodiment, the waveform equalization procedure is carried out, with the quality of the output signal v(n) being fed back. This minimizes deterioration in characteristic, while allowing the waveform equalizer to achieve a further reduction in power consumption. Moreover, the circuit size of the waveform equalizer is further reduced.

It should be noted that instead of the output signal v(n), an error signal err from an error detector 20 may be inputted to the signal quality evaluation unit 50. In that case, to calculate the quality evaluation value evl, the inputted error signal err may be used as it is, or an averaged signal may be used.

(Third Embodiment)

In the first and second embodiments, the multiplier units 12 in the digital filter 10 include a certain number of multipliers in each tap. Nevertheless, a necessary number of multipliers may be dynamically allocated to each tap. More specifically, a given amount of operation resources that the waveform equalizer has may be allocated among the taps in accordance with the respective operation accuracy control values a from the operation accuracy control unit 40.

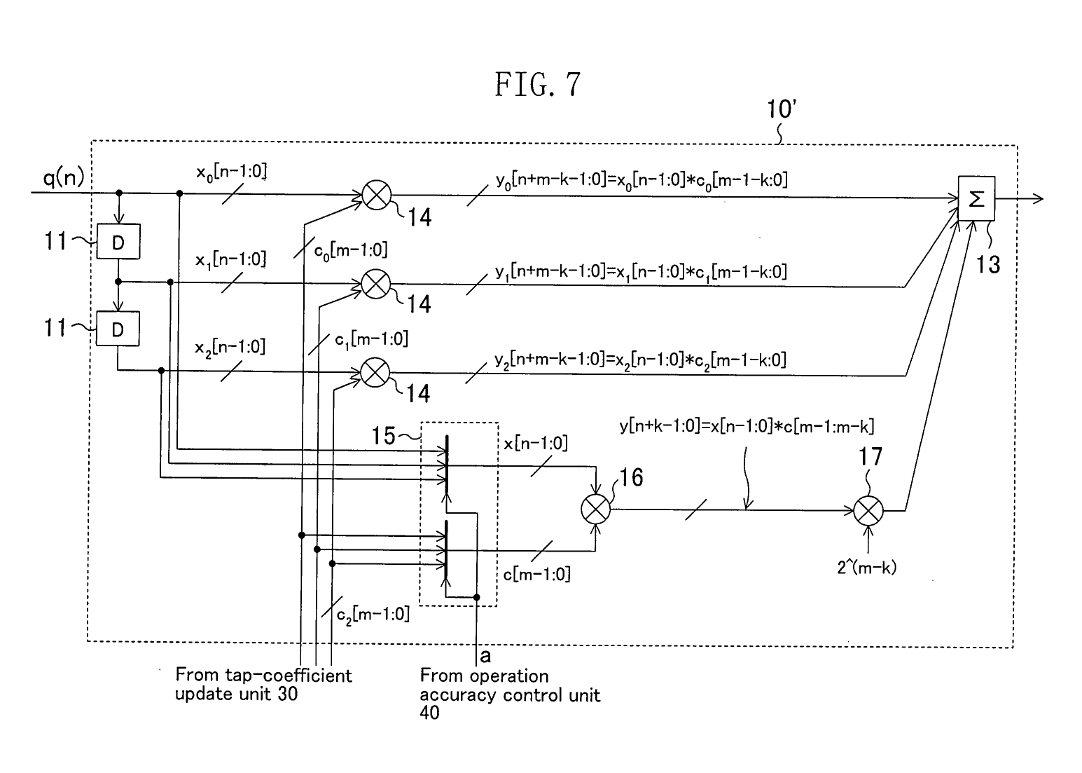

FIG. 7 illustrates the configuration of a digital filter in accordance with a third embodiment of the present invention. The digital filter 10 of this embodiment includes three multipliers 14, a selection unit 15, and multipliers 16 and 17. The multipliers 14 multiply n-bit tap values x₀, x₁, and X₂ by their corresponding m-bit tap coefficients c₀, c₁, and c₂. The selection unit 15 selects a combination of any one tap value x and any one tap coefficient c from among the tap values x₀ through x₂ and the tap coefficients c₀ through c₂ in accordance with the operation accuracy control value a. The multipliers 16 and 17 serve as operation resources. It should be noted that the digital filter 10 can be replaced by the digital filters 10 illustrated in FIGS. 1 and 5.

Each of the multipliers 14 performs the multiplication using only lower-order (m−k) bit(s) of the respective tap coefficient cᵢ (i=0, 1, 2) and outputs (n+m−k)-bit operation result yᵢ(i=0, 1, 2). That is, each of the multipliers 14 performs its operation with lowered accuracy.

The multiplier 16 performs a multiplication on higher-order k bit(s) of the tap coefficient c and the tap value x selected by the selection unit 15. The multiplier 17 shifts the output from the multiplier 16 by (m−k) bits so that the output from the multiplier 16 is aligned with the output y from the multipliers 14 in terms of bit position. Then, an adder 13 performs cumulative sum of the outputs from the multipliers 14 and 17.

By the above configuration, the operation on one of the tap values x₀ through x₂ selected by the selection unit 15 is performed with high accuracy, while the operations on the others are carried out with low accuracy.

As described above, in this embodiment, the limited operation resources are allocated preferentially to those taps that require highly accurate operations. This optimizes the operation resources that the digital filter 10 should have, while allowing a reduction in power consumption by, and circuit size of, the waveform equalizer.

It should be noted that more multipliers 16 and 17 may be provided as the operation resources. In addition, operation resources that function blocks other than the digital filter 10 have may be allocated.

Furthermore, all of the multipliers 14 have equal operation accuracy in the above description, but may have different operation accuracy. Even in that case, effects similar to those mentioned above can be achieved.

### INDUSTRIAL APPLICABILITY

The waveform equalizers in accordance with the present invention function effectively in digital-broadcast receivers and other devices in which power consumption is required to be reduced.

1. A waveform equalizer comprising:
a digital filter for performing convolution operation for a plurality of tap values each of which is obtained by delaying an input signal for a given amount of time and a plurality of tap coefficients corresponding to those tap values, thereby generating an output signal;
an error detector for detecting an error in the output signal from the digital filter;
a tap-coefficient update unit for updating the tap coefficients based on the error detected by the error detector; and
an operation accuracy control unit for calculating operation accuracy control values that correspond to respective taps in the digital filter,
wherein the digital filter changes accuracy with which the convolution operation is performed, in accordance with the operation accuracy control values calculated by the operation accuracy control unit.

2. The waveform equalizer of claim 1, wherein the operation accuracy control unit has size-comparing units each of which compares in terms of size one of the tap coefficients with a predetermined threshold value corresponding to the tap coefficient, and then outputs comparison result as the operation accuracy control value corresponding to the tap coefficient.

3. The waveform equalizer of claim 1, wherein the digital filter includes multiplier units each of which performs a multiplication for one of the tap values and the tap coefficient corresponding to the tap value and changes effective bit length in accordance with the operation accuracy control value corresponding to the tap value.

4. The waveform equalizer of claim 3, wherein each of the multiplier units has an information acquiring unit for acquiring at least either one or more higher-order bits or one or more lower-order bits of an associated one of the tap coefficients, and if the operation accuracy control value instructs to lower the accuracy of the convolution operation in the digital filter, the multiplier unit masks either the higher-order or lower-order bits of the tap coefficient acquired by the information acquiring unit.

5. The waveform equalizer of claim 1, further comprising:
a signal quality evaluation unit for evaluating quality of the output signal from the digital filter,
wherein the operation accuracy control unit calculates the operation accuracy control values from a quality evaluation value generated by the signal quality evaluation unit, and if the quality evaluation value indicates that the quality of the output signal is relatively low, the operation accuracy control unit calculates the operation accuracy control values so that the accuracy of the convolution operation in the digital filter is raised, while if the quality evaluation value indicates that the quality of the output signal is relatively high, the operation accuracy control unit calculates the operation accuracy control values so that the accuracy is lowered.

6. The waveform equalizer of claim 5, wherein
the operation accuracy control unit includes:
an evaluation-value storing unit for storing a past quality evaluation value of the output signal;
a comparison unit for comparing a new quality evaluation value of the output signal with the quality evaluation value stored in the evaluation-value storing unit;
a plurality of operation accuracy control sub-units which are provided corresponding to the respective taps in the digital filter, and each of which calculates a corresponding one of the operation accuracy control values; and
a control unit for controlling the operation accuracy control sub-units in a time-sharing manner,
wherein if a comparison result from the comparison unit indicates that the new quality of the output signal is higher than the past quality of the output signal, each of the operation accuracy control sub-units calculates the operation accuracy control value so that the accuracy of the convolution operation in the digital filter is lowered, while if the comparison result indicates that the new quality of the output signal is lower than the past quality, each of the operation accuracy control sub-units calculates the operation accuracy control value so that the accuracy is raised.

7. The waveform equalizer of claim 1, wherein the digital filter allocates operation resources that the waveform equalizer has, among the respective taps in accordance with the operation accuracy control values.
